(19) United States
(12) Patent Application Publication
(10) Pub. No.: US 2025/0197434 A1
(43) Pub. Date: Jun. 19, 2025

(54) NOVEL MULTI-COMPONENT ORGANOMETALLIC COMPOUND, COMPOSITION CONTAINING SAME FOR SOLUTION PROCESS, AND METHOD FOR MANUFACTURING THIN FILM USING SAME

(71) Applicant: KOREA RESEARCH INSTITUTE OF CHEMICAL TECHNOLOGY, Daejeon (KR)

(72) Inventors: Jong Sun LIM, Daejeon (KR); Da Som SONG, Daejeon (KR); Chang Gyoun KIM, Daejeon (KR); Woo Seok SONG, Daejeon (KR); Sun Young SHIN, Daejeon (KR); Sung MYUNG, Daejeon (KR); Taek Mo CHUNG, Daejeon (KR)

(73) Assignee: KOREA RESEARCH INSTITUTE OF CHEMICAL TECHNOLOGY, Daejeon (KR)

(21) Appl. No.: 18/730,996

(22) PCT Filed: Mar. 15, 2023
(86) PCT No.: PCT/KR2023/003440

§ 371 Date: Jan. 31, 2025

(30) Foreign Application Priority Data
Mar. 30, 2022 (KR) 10-2022-0039694
Sep. 6, 2022 (KR) 10-2022-0112847

(51) Int. Cl. C07F 19/00; C23C 18/04; C23C 18/12; H10F 71/00; H10F 77/169

(52) U.S. Cl. CPC C07F 19/00; C23C 18/04; C23C 18/1204; H10F 71/128; H10F 77/169

(57) ABSTRACT

The present invention relates to a novel multi-component organometallic compound, a composition containing same for a solution process, a method for manufacturing a thin film by using same, and a method for manufacturing an optical sensor by using same.

### TECHNICAL FIELD

The present disclosure relates to a novel multi-component organometallic compound, a composition containing same for a solution process, and a method for manufacturing a thin film using same. More specifically, the present disclosure pertains to a novel multi-component organometallic compound, a composition containing same for a solution process, and a method for manufacturing a thin film using same, which, through a solution process, enables the production of high-quality ternary, quaternary, or quinary transition metal thin films, transition metal oxide thin films, or transition metal chalcogenide thin films with improved thermal stability.

### Background Art

Among recently researched two-dimensional materials, transition metal dichalcogenides (TMDC) find potential applications in various fields.

For example, two-dimensional semiconductors containing transition metal chalcogenides such as MoS₂, WS₂, etc. exhibit unique carrier transport properties that differ significantly from conventional thin films or bulk materials due to the two-dimensional interactions among the constituent atoms. These materials are expected to provide high mobility, high speed, and low power consumption characteristics.

In particular, in addition to being useful in high-mobility and low-power semiconductor devices, these two-dimensional semiconductors offer transparent and flexible properties due to their semiconductor layers being a few nanometers thick. Additionally, materials that display indirect transition properties in bulk or in ordinary thin film states exhibit direct transition properties when manufactured as monolayers or a few layers thick. This enhances their photoresponsivity, making them highly suitable for photonic devices.

MoS₂, a representative transition metal di-chalcogenide (TMDC) material, is known to have an indirect transition characteristic with a bandgap of 1.2-1.3 eV in thick film or bulk states. However, when thinned to a monolayer or up to five layers, MoS₂ exhibits direct transition properties with a bandgap of 1.8-1.9 eV for a monolayer, which gradually decreases to the bulk state bandgap as the number of layers increases. Research is actively being conducted to use the material as the active layer in high-mobility thin-film transistors.

Additionally, WS₂, as a transition metal di-chalcogenide (TMDC) material, can be grown into thin films using chemical vapor deposition (CVD). For example, after depositing a tungsten (W) thin film on a silicon dioxide (SiO₂) substrate, the film is heated in a CVD system with sulfur (S) gas supplied to grow WS₂. The WS₂ can then be transferred to an ITO/glass substrate. This technology is useful for developing semiconductors or solar cells because it is easily applicable to large areas.

Furthermore, transition metal di-chalcogenide (TMDC) materials such as MoS₂ and WS₂ are expected to be useful as catalysts for reactions such as hydrocracking and hydrogen evolution reactions, as well as in the development of semiconductors, sensors, or solar cells.

To form thin films containing transition metal chalcogenides, methods such as chemical vapor deposition (CVD), atomic layer deposition (ALD), or solution processes are used. When manufacturing uniform tungsten or molybdenum thin films, the deposition degree and control characteristics are determined by the properties of the metal precursors, necessitating the development of superior metal precursors.

Recently, attempts have been made to manufacture transition metal chalcogenide materials (thin films) such as MoS₂ and WS₂ by introducing chalcogen elements (S) directly into the metal source-containing precursor itself without separately or sequentially adding the chalcogen elements.

In this case, during the manufacturing of transition metal chalcogenide thin films like MoS₂ and WS₂, the introduction of chalcogen elements as ligands in the metal precursor without separately adding chalcogen elements (S) in the thin film manufacturing process provides the advantage of forming more uniform thin films more conveniently.

With the induction of strong light-matter interactions therein, two-dimensional transition metal chalcogenide materials such as MoS₂ thin films possess a high light absorption coefficient relative to their thickness and thus can be applied to the implement of high-performance photonic sensors. However, most transition metal chalcogenide materials manufactured using conventional techniques, including MoS₂, have bandgaps in the visible light range and thus require having photosensitivity enhanced for infrared sensor applications. Existing theoretical calculations suggest that substituting Ni atoms at Mo sites in MoS₂ can decrease the bandgap, potentially resulting in improved material properties.

With respect to related conventional technologies for precursors used in thin film formation, reference may be made to Korean Patent No. 10-2007-0073636 A, which studies a method for preparing tungsten or molybdenum precursors containing diamine ligands, and Korean Patent No. 10-2015-0084757 A, which discloses a molybdenum precursor composed of a cyclopentadienyl group and an imido group as ligands. However, these technologies cannot be applied to direct formation of WS₂ or MoS₂ thin films. They also require improvements in thermal stability, chemical reactivity, and volatility. Furthermore, they do not suggest methods for manufacturing two-dimensional MoS₂ and WS₂ thin films doped with transition metals.

To manufacture two-dimensional MoS₂ and WS₂ thin films doped with transition metals, cumbersome multiple electrochemical processes are required, highlighting the need for a precursor that can solve these issues simultaneously.

Therefore, there is a need for developing a novel multicomponent molybdenum or tungsten organometallic compound as a solution process precursor with improved thermal stability, capable of easily forming metal thin films, metal oxide thin films, or metal chalcogenide thin films at low temperatures, as well as a solution process composition containing the compound and a manufacturing process for thin films with improved properties using the composition.

### DISCLOSURE

### Technical Problem

The present disclosure aims primarily to provide a novel organometallic compound as a precursor capable of manufacturing transition metal-doped ternary, quaternary, or quinary metal thin films or metal chalcogenide thin films with improved thermal stability.

Also, the present disclosure is to provide a novel method for manufacturing the organometallic compound.

In addition, the present disclosure is to provide a method for manufacturing a ternary, quaternary, or quinary metal thin film, a ternary, quaternary, or quinary metal oxide thin film, or a ternary, quaternary, or quinary metal chalcogenide thin film using the organometallic compound as a precursor.

Furthermore, the present disclosure is to provide a novel solution process composition including a multicomponent organometallic compound which allows for manufacturing of a heterometallic chalcogenide thin film with a molybdenum chalcogenide material doped with an additional transition metal.

Moreover, the present disclosure is to provide a novel method for manufacturing a heterometallic chalcogenide thin film using the solution process composition.

### Technical Solution

To achieve the technical aims, the present disclosure provides an organometallic compound represented by Chemical Formula A or B:

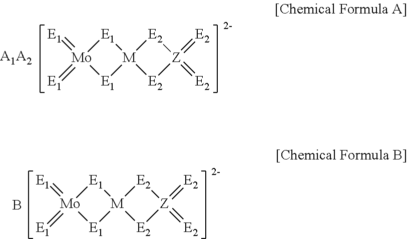

wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄⁺, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20,
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
   wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

Also, the present disclosure provides a method for manufacturing an organometallic compound represented by Chemical Formula A or B, using a metal halide compound represented by the following Compound M, a molybdenum chalcogenide represented by the following Compound C1, and a transition metal chalcogenide represented by the following Compound C2 as respective reactants:

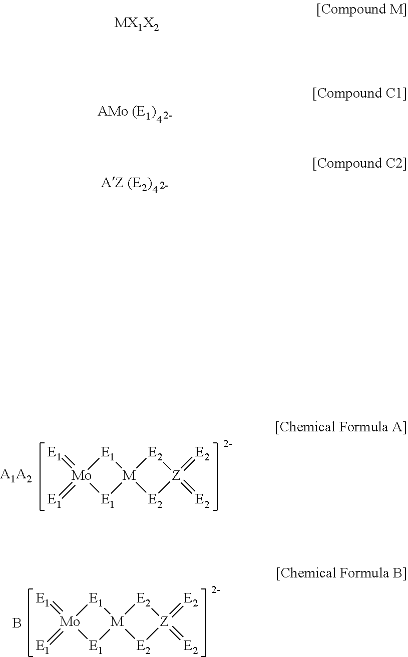

in Compound M,
X₁ and X₂, which are same or different, are each independently a halogen atom selected from F, Cl, Br, and I,
in Chemical Formulas C1 and C2,
A means a divalent cation or two identical or different monovalent cations corresponding to Mo(E₁)₄²⁻,
A′ means a divalent cation or two identical or different monovalent cations corresponding to Z(E₂)₄²⁻,
in Chemical Formula C2,
Z is Mo or W,
in Chemical Formulas A and B and Compounds C1 and C2,
E₁ and E₂, which are same or different, are each independently sulfur (S) or selenium (Se), and
M, Z, A₁, A₂, and B in Compound M and Chemical Formulas A and B are each as defined above.

In addition, the present disclosure provides a solution process composition including an organometallic compound represented by the following Chemical Formula A or B for forming a heterometallic chalcogenide thin film:

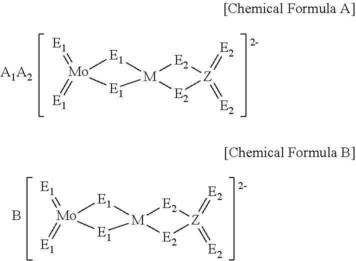

wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄⁺, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20, and
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
   wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

In addition, the present disclosure provides a method for manufacturing a heterometallic chalcogenide thin film, the method including the steps of: (a) coating a substrate with the solution process composition; and (b) applying heat treatment or external energy to the solution process composition-coated substrate.

Furthermore, the present disclosure provides a heterometallic chalcogenide thin film manufactured by the method for manufacturing a heterometallic chalcogenide thin film according to the present disclosure.

Moreover, the present disclosure provides a photosensor or electronic device including the heterometallic chalcogenide thin film.

### Advantageous Effects

The organometallic compound represented by Chemical Formula A or B according to the present disclosure can be used as precursors for forming metal thin films, metal oxide thin films, or metal chalcogenide thin films via solution processing and are particularly useful as precursors for forming metal chalcogenide thin films.

Moreover, the organometallic compound represented by Chemical Formula A or B exhibits improved thermal stability, allowing for the formation of large-area or uniform thin films. Additionally, since the compound includes sulfur (S) and/or selenium (Se) within the precursor, the compound facilitates the easy formation of transition metal chalcogenide thin films using a single precursor through a one-step annealing process, without the need for additional chalcogen elements.

Furthermore, the metal chalcogenide thin film manufactured with the organometallic compound of the present disclosure employs a precursor bearing a cationic leaving group instead of conventional metal halide precursors, thus enjoying the advantage of being free of the contamination and corrosion of the thin film manufacturing apparatus which is attributed to the generation of halogen gas during the manufacturing process.

The solution process composition according to the present disclosure can be formed into thin films with thermal stability and excellent properties and thus enables the manufacture of large-area and highly uniform heterometallic chalcogenide thin films. Additionally, since the precursor contains both heterometallic and chalcogen elements within a single molecule, it allows for the easy formation of heterometallic chalcogenide thin films without the need for additional chalcogen elements when used as a solution process composition.

The heterometallic chalcogenide thin films manufactured using the solution process composition of the present disclosure demonstrate superior performance as photonic sensors compared to existing commercial materials, particularly offering excellent detection of visible and infrared light wavelengths.

### DESCRIPTION OF DRAWINGS

FIG. 1(a) shows the X-ray crystal structure of (Ph₄P)₂[Ni(MoS₄)₂)] compound prepared according to Preparation Example 8 of the present disclosure, and FIG. 1(b) shows the X-ray crystal structure of (Ph₄P)₂[(MoS₄)Pd(WS₄)] compound prepared according to Preparation Example 7 of the present disclosure.

FIG. 2(a) is a thermogravimetric analysis (TGA) curve of the (Ph₄P)₂[Ni(MoS₄)₂)] compound prepared according to Preparation Example 8 of the present disclosure, and FIG. 2(b) is a TGA curve of the (Ph₄P)₂[(MoS₄)Pd(WS₄)] compound prepared according to Preparation Example 7 of the present disclosure.

FIG. 3(a) shows images of the film prepared by spin-coating the (Ph₄P)₂[Ni(MoS₄)₂)] compound according to Preparation Example 8 of the present disclosure, and FIG. 3(b) is an image of a film prepared by spin-coating the (Ph₄P)₂[(MoS₄)Pd(WS₄)] compound according to Preparation Example 7 of the present disclosure.

FIG. 4(a) shows optical microscope images of the NiₓMo_{y}S_{z} thin film prepared in Example 4 and the Ni_{0.08}Mo_{0.35}S_{0.57} heterometallic chalcogenide thin films synthesized from same under the thermal decomposition conditions at 400° C., 500° C., and 600° C. in Example 4, and FIG. 4(b) shows optical microscope images of the PdₓMo_{y}W_{y}S_{z} thin film prepared in Example 5 and the WMoPd_{0.5}S_{1.8} heterometallic chalcogenide thin films synthesized from same under the thermal decomposition conditions at 400° C., 500° C., 600° C., 700° C., 800° C., and 900° C. in Example 5.

FIG. 5(a) shows X-ray photoelectron spectroscopy spectra for the two-dimensional heterometallic chalcogenide (NiₓMo_{y}S_{z}) thin film manufactured in Example 4 of the present disclosure, and FIG. 5(b) shows X-ray photoelectron spectroscopy spectra for the two-dimensional heterometallic chalcogenide (PdₓMo_{y}W_{y}S_{z}) thin film prepared in Example 5 of the present disclosure.

FIG. 6(a) shows Raman spectra of the two-dimensional heterometallic chalcogenide (NiₓMo_{y}S_{z}) thin film manufactured according to Example 4 and FIG. 6(b) shows Raman spectra for the two-dimensional heterometallic chalcogenide (PdₓMo_{y}W_{y}S_{z}) thin film prepared according to Example 5 of the present disclosure.

FIG. 7(a) shows transmission electron microscopy images and energy dispersive X-ray spectroscopy elemental mapping (EDS) results for the heterometallic chalcogenide (Ni_{0.08}Mo_{0.35}S_{0.57}) thin film synthesized in Example 4 of the present disclosure and FIG. 7(b) shows transmission electron microscopy images and energy dispersive X-ray spectroscopy elemental mapping (EDS) results for the PdₓMo_{y}W_{y}S_{z} thin film prepared according to Example 5 of the present disclosure.

FIG. 8 shows the atomic force microscope images of the two-dimensional Ni_{0.08}Mo_{0.35}S_{0.57} thin film prepared according to Example 4 of the present disclosure.

FIG. 9 shows the comparison of optical properties between the Ni_{0.08}Mo_{0.35}S_{0.57} sensor prepared according to Example 11 of the present disclosure and conventional optical sensors.

FIG. 10 shows the photocurrent measurement results of the optical sensor prepared according to Example 10 of the present disclosure under varying applied voltages and laser intensities for visible light (532 nm).

FIG. 11 shows the photocurrent measurement results of the optical sensor prepared according to Example 11 of the present disclosure under varying applied voltages and laser intensities for visible light (532 nm) and near-infrared light (1064 nm).

FIG. 12(a) shows the photoelectric properties of the WMoPd_{0.5}S_{1.8} semiconductor layered material for visible light (532 nm) according to the present disclosure, and FIG. 12(b) shows the photoelectric properties of a conventional MoS₂ semiconductor layered material for visible light (532 nm).

### MODE FOR INVENTION

Below, a detailed description will be given of the present disclosure. Unless defined otherwise, all technical and scientific terms used herein have the same meaning as commonly understood by one of ordinary skill in the art to which the invention pertains. Generally, the nomenclature used herein and the experiment methods, which will be described below, are those well known and commonly employed in the art.

Throughout the specification, when a portion may “include” or “comprise” a certain constituent element, unless explicitly described to the contrary, it may not be construed to exclude another constituent element but may be construed to further include other constituent elements.

Intensive and thorough research conducted by the present inventors with the aim of achieving the aforementioned technical subjects and developing a precursor for the preparation of multicomponent metal chalcogenide thin film with excellent properties resulted in the finding that the metal halide (MX₁X₂) corresponding to the central metal (M) in the compound represented by Chemical Formula A or B is reacted with a molybdenum chalcogenide represented by the following Compound C1 and a transition metal chalcogenide represented by the following Compound C2,

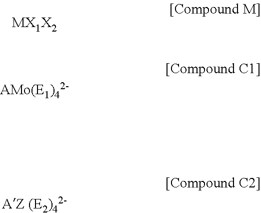

to produce the divalent anionic moiety

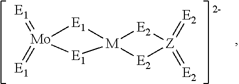

of the structure of Chemical Formula A or B and the resulting complex is reacted with a salt containing A₁ and A₂ or a salt containing B through cation exchange to afford the organometallic compound represented by Chemical Formula A or B according to the present disclosure.

The organometallic compound, represented by Chemical Formula A or B, obtained according to the present disclosure can be used as A precursor for manufacturing ternary or quaternary metal chalcogenide thin films via solution processing.

That is, the organometallic compound represented by Chemical Formula A or B has the ternary organometallic compound structure in which two sulfur (S) atoms or selenium (Se) atoms each form covalent bonds with both molybdenum (Mo) and the central metal (M) and two other sulfur (S) atoms or selenium (Se) atoms each with both the central metal (M) and the transition metal (Z), thus serving as respective bridges therebetween, with each of the terminal molybdenum and transition metal (Z) bonding to two identical or different atoms selected from sulfur (S) and selenium (Se). This bridged moiety is divalently anionic in entirety while A₁ and A₂ are together divalently cationic in Chemical Formula A and B alone is responsible for a divalent cation in Chemical Formula B.

Through the structure of Chemical Formula A or B, the compounds exhibit excellent chemical and thermal stability in solution processing. Additionally, by introducing sulfur (S) and/or selenium (Se) as chalcogen elements within the transition metal-containing precursor itself, the compound can be used as a useful precursor for forming transition metal chalcogenide thin films without the need for additional chalcogen elements. This confirms the utility of the present disclosure.

That is, the organometallic compounds represented by Chemical Formula A or Chemical Formula B in the present disclosure contain sulfur (S) and/or selenium (Se) as chalcogen elements within the transition metal-containing precursor itself. This provides the advantage of being able to manufacture ternary transition metal chalcogenide thin films without the simultaneous or sequential addition of separate chalcogen elements (S or Se) during the manufacturing process. Furthermore, although the production of transition metal-doped two-dimensional MoS₂/WS₂ thin films typically requires multiple electrochemical processing steps, the organometallic compounds of the present disclosure solve these issues simultaneously.

Additionally, metal chalcogenide thin films produced from the organometallic compound of the present disclosure can form a structure where divalent transition metal ions such as Pd²⁺, Ni²⁺, and Co²⁺ are doped into the surface of two-dimensional transition metal chalcogenide thin film structures. When these divalent transition metals are absorbed into the two-dimensional structure, the structure can increase the catalytic activity for reactions such as hydrocracking and hydrogen evolution. These structures are expected to exhibit excellent activity as active sites for hydrogen adsorption and reduction reactions, making them highly effective as electrodes for hydrogen generation reactions.

Below, a detailed description will be given of the present disclosure.

The present disclosure provides an organometallic compound represented by the following Chemical Formula A or B:

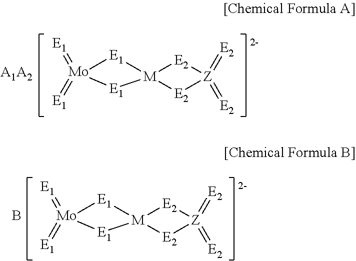

wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄+, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20, and
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

Here, the organometallic compound represented by Chemical Formula A or B is a ternary organometallic compound structured to have a sulfur (S) or selenium (Se) bridge between molybdenum (Mo) and the central metal (M) through covalent bonds and between the central metal (M) and the transition metal (Z=Mo or W) through covalent bonds, with each of the terminal molybdenum and transition metal (Z) bonding to two identical or different atoms selected from sulfur (S) and selenium (Se). This bridged moiety is divalently anionic in entirety while the corresponding cationic component includes two monovalent cations selected from H⁺, Li⁺, Na⁺, K⁺, Rb⁺, Cs⁺, NH₄+, N⁺(R₁R₂R₃R₄), and a monovalent imidazole cation of 1 to 10 carbon atoms or any one divalent cation selected from Ca²⁺, Mg²⁺, (R₁R₂R₃) N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆.

With such a structure, the organometallic compound represented by Chemical Formula A or B according to the present disclosure exhibits thermal stability and thus can be applied as a precursor for ternary metal thin films, ternary metal oxide thin films, or ternary metal chalcogenide thin films, which are usable in solution processes.

Additionally, as described above, since sulfur (S) and/or selenium (Se) chalcogen elements are bonded to molybdenum, metal (Z), or the central metal (M) atoms within the precursor compound molecule that includes transition metal sources, the compound has the additional advantage of being able to be used as a chalcogen sources when employed as a precursor for manufacturing ternary transition metal chalcogenide thin films.

In the organometallic compounds represented by Chemical Formula A according to the present disclosure, the monovalent cations A₁ and A₂ are same or different and preferably may each be independently, P⁺(R₁R₂R₃R₄). The organometallic compounds including P⁺(R₁R₂R₃R₄) are expected to stabilize the layered structure of the metal dichalcogenide thin films by acting as capping agents due to the planar structure of the aryl chains or the chain structure of the alkyl chains in the compound during the thin film manufacturing process.

Furthermore, in the organometallic compounds represented by Chemical Formula A according to the present disclosure, the monovalent cations A₁ and A₂ are same or different and may each be independently, for example, any one selected from H⁺, tetraphenylphosphonium, cetyltrimethylammonium (CTA), tetraethylammonium, 1-ethyl-3-methylimidazolium, or pyridinium.

In addition, in the organometallic compounds represented by Chemical Formula A according to the present disclosure, when A₁ and A₂ are same and different and are each independently P⁺(R₁R₂R₃R₄), R₁ to R₄ are same or different and may each be independently any one selected from a substituted or unsubstituted aryl of C6-C20 and a substituted or unsubstituted heteroaryl of C2-C20, where identical substituents may be employed for R₁ to R₄.

The central metal (M) used in the organometallic compounds represented by Chemical Formula A or B according to the present disclosure may be preferably one selected from Ni, Co, Fe, Ru, Rh, Pd, Os, Ir, and Pt, and more preferably Ni, Co, Fe, and Pd.

Furthermore, the present disclosure provides a method for manufacturing metal thin films, metal oxide thin films, or metal chalcogenide thin films using the organometallic compound represented by Chemical Formula A or B as a metal precursor, and the thin films obtained by the manufacturing method. The manufacturing may be performed using a solution process method where the precursor is dissolved in a solvent and coated to form thin films.

Here, the metal chalcogenide thin films may include metal dichalcogenide compounds.

By the solution process method according to the present disclosure, the organometallic compound represented by Chemical Formula A or B may preferably be used as a precursor for manufacturing metal dichalcogenide compounds.

In other words, the present disclosure provides a solution process composition containing the organometallic compound represented by Chemical Formula A or Chemical Formula B.

The solution process composition may further include an organic solvent. Suitable examples of the organic solvent include toluene, tetrahydrofuran, hexane, cyclohexane, acetonitrile, dimethylformamide, dimethyl sulfoxide (DMSO), and isopropyl alcohol (IPA), and a combination thereof, but are not limited thereto. Preferably, at least one selected from acetonitrile, dimethylformamide, dimethyl sulfoxide (DMSO), and isopropyl alcohol (IPA) may be used.

Additionally, the solution process composition may contain the organometallic compound represented by Chemical Formula A or Chemical Formula B in an amount of from 0.05 to 90% by weight based on the total weight thereof. If the content of the organometallic compounds is less than 0.05% by weight, the thin film formation rate becomes very slow due to the long process time, significantly reducing productivity. If the content exceeds 90% by weight, it becomes difficult to obtain uniform metal thin films, metal oxide thin films, or metal chalcogenide thin films due to the excess organometallic compounds.

The present disclosure provides a method for manufacturing an organometallic compound represented by Chemical Formula A or B by using as reactants a metal halide compound represented by the following Compound M, a molybdenum chalcogenide represented by the following Compound C1, and a transition metal chalcogenide represented by the following Compound C2:

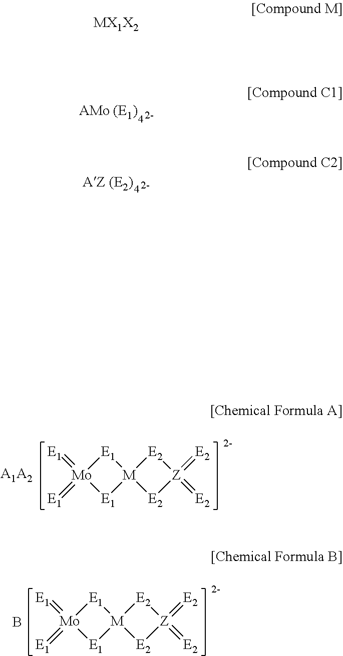

in Compound M,
X₁ and X₂, which are same or different, are each independently a halogen atom selected from F, Cl, Br, and I,
in Chemical Formulas C1 and C2,
A means a divalent cation or two identical or different monovalent cations corresponding to Mo(E₁)₄²⁻,
A′ means a divalent cation or two identical or different monovalent cations corresponding to Z(E₂)₄²⁻,
in Chemical Formula C2,
Z is Mo or W,
in Chemical Formulas A and B and Compounds C1 and C2,
E₁ and E₂, which are same or different, are each independently sulfur (S) or selenium (Se), and in Compound M and Chemical Formulas A and B,
M is a metal element selected from Ni, Co, Fe, Ru, Rh, Pd, Os, Ir, Pt, Ti, Al, Cu, Mg, V, B, Cr, Zr, and Zn,
A₁ and A₂, which are same or different, are each independently a monovalent cation selected from H⁺, Li⁺, Na⁺, K⁺, Rb⁺, Cs⁺, NH₄⁺, N⁺(R₁R₂R₃R₄), a monovalent imidazole cation of 1 to 10 carbon atoms, a monovalent pyridine cation of 1 to 10 carbon atoms, and a monovalent cation of P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20, and
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
   wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

Here, A and A′ in Chemical Formulas C1 and C2 are each a divalent cation or represent two monovalent cations corresponding to Mo(E₁)₄²⁻or W(E₂)₄²⁻. Examples of the divalent cation corresponding to Mo(E₁)₄²⁻or Z(E₂)₄²⁻ includes Ca²⁺, Mg²⁺, (R₁R₂R₃) N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆. In this regard, R₁ to R₆ are as defined above.

In addition, examples of the monovalent cations corresponding to Mo(E₁)₄²⁻or Z(E₂)₄²⁻ include H⁺, Li⁺, Na⁺, K⁺, Rb⁺, Cs⁺, NH₄+, N⁺(R₁R₂R₃R₄), a monovalent cation of 1 to 10 carbon atoms, a monovalent pyridine cation of 1 to 10 carbon atoms, and P⁺(R₁R₂R₃R₄), wherein R₁ to R₄ are as defined above.

In the method for manufacturing an organometallic compound represented by Chemical Formula A or B according to the present disclosure, the

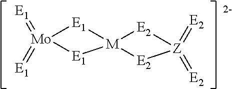

moiety obtained after the reaction of the metal halide compound represented by Compound M, the molybdenum chalcogenide represented by Compound C1, and the transition metal chalcogenide represented by Compound C2 is reacted with a salt containing A₁ and A₂, or a salt containing B through cationic exchange to afford the compound represented by Chemical Formula A or Chemical Formula B.

That is, the compound represented by Chemical Formula A is prepared when the metal halide compound represented by Compound M, the molybdenum chalcogenide represented by Compound C1, and the transition metal chalcogenide represented by Compound C2 are used as reactants and a monovalent cation (a salt containing A₁ and A₂) selected from H⁺, Li⁺, Na⁺, K⁺, Rb⁺, Cs⁺, NH₄+, N⁺(R₁R₂R₃R₄), a monovalent imidazole cation of 1 to 10 carbon atoms, a monovalent pyridine cation of 1 to 10 carbon atoms, and P⁺(R₁R₂R₃R₄) is used as a cationic component that is capable of inducing a stable chemical structure by forming an ionic bond with the anion in the resulting ternary metal complex. When a divalent cation (a salt containing B) selected from Ca²⁺, Mg²⁺, (R₁R₂R₃) N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆, the compound represented by Chemical Formula B can be prepared.

Here, in the method for manufacturing Compound A according to the present disclosure, a halide containing the monovalent cation represented by P⁺(R₁R₂R₃R₄) may be preferably used as the salt containing A₁ and A₂ which are mediator for cation exchange. In this regard, R₁ to R₄ are same or different and are each independently any one selected from a substituted or unsubstituted aryl of C6-C20 and a substituted or unsubstituted heteroaryl of C2-C20. Preferably, R₁ to R₄ may be same.

In addition, in the method for manufacturing Compound B according to the present disclosure, a halide containing the divalent cation represented by (R₁R₂R₃)P⁺—R—P⁺(R₄R₅R₆) may be used as the salt containing B which serves as a mediator for cation exchange. In this regard, R₁ to R₆ may be same or are each independently any one selected from a substituted or unsubstituted aryl of C6-C20 and a substituted or unsubstituted heteroaryl of C2-C20. Preferably, R₁ to R₆ may be same, and the substituent R may be any one selected from an unsubstituted linear, branched, or cyclic alkylene of C1-C20, a substituted or unsubstituted linear, branched, or cyclic halogenated alkylene of C1-C20, a substituted or unsubstituted cycloalkylene of C1-C2, a substituted or unsubstituted arylene of C6-C20, and a substituted or unsubstituted heteroarylene of C2-C20.

In the method for manufacturing Compound A or B according to the present disclosure, the metal (M) in Compound M may be preferably any one metal element selected from Ni, Co, Fe, Ru, Rh, Pd, Os, Ir, and Pt and more preferably from Ni, Co, Fe, and Pd.

Here, when an organic solvent is used in the manufacturing of the organometallic compounds represented by Chemical Formula A or B, suitable examples of the organic solvent include toluene, tetrahydrofuran, hexane, cyclohexane, acetonitrile, dimethylformamide, dimethyl sulfoxide (DMSO), and isopropyl alcohol (IPA), but are not limited thereto. Preferably, acetonitrile, dimethylformamide, dimethyl sulfoxide (DMSO), and isopropyl alcohol (IPA) may be used.

The reaction preferably proceeds under the organic solvent at a temperature range of 0 to 100° C., more preferably to 40° C., for 12 to 24 hours, whereby the compounds represented by Chemical Formula A or B can be produced.

Additionally, separation of the product from by-products or unreacted materials generated during the reaction can be carried out through sublimation, distillation, extraction, column chromatography, or recrystallization to obtain high-purity novel organometallic compounds.

At room temperature, the high-purity organometallic compound thus obtained, represented by Chemical Formula A or B, may be solid or liquid, thermally stable, and soluble in organic solvents, and thus can be utilized in solution processes.

Furthermore, the present disclosure provides a solution process composition and a method for manufacturing a heterometallic chalcogenide thin films using same. These aspects will be described in more detail below.

The present disclosure provides a solution process composition for forming a heterometallic chalcogenide thin film, the composition including the organometallic compound represented by Chemical Formula A or B:

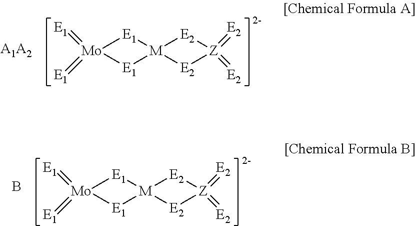

wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄+, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20, and
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
   wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

Here, the organometallic compound represented by Chemical Formula A or B is an organometallic compound structured to have a sulfur (S) or selenium (Se) bridge between the terminal molybdenum (Mo) and the central metal (M) through covalent bonds and between the central metal (M) and the transition metal Z (Mo or W) through covalent bonds, with each of the terminal molybdenum and transition metal (Z) bonding to two identical or different atoms selected from sulfur (S) and selenium (Se). This bridged moiety is divalently anionic in entirety while the corresponding cationic component includes two monovalent cations selected from H⁺, Li⁺, Na⁺, K⁺, Rb⁺, Cs⁺, NH₄+, N⁺(R₁R₂R₃R₄), and a monovalent imidazole cation of 1 to 10 carbon atoms or any one divalent cation selected from Ca²⁺, Mg²⁺, (R₁R₂R₃) N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆.

With such a structure, the organometallic compound represented by Chemical Formula A or B according to the present disclosure exhibits thermal stability in solution processes and thus can be applied as a precursor for heterometallic chalcogenide thin films.

As used herein, the term “heterometal” means pertaining to different types of transition metals. In the present disclosure, the central metal (M) within the molecular structure of Chemical Formula A or B is different from opposite terminal metals molybdenum or tungsten atoms and may include any one selected from Ni, Co, Fe, Ru, Rh, Pd, Os, Ir, Pt, Ti, Al, Cu, Mg, V, B, Cr, Zr, and Zn.

In addition, as described in the foregoing, since sulfur (S) and/or selenium (Se) chalcogen elements are bonded to molybdenum, Z (Mo or W), and the central metal (M) atoms within the precursor compound molecule that includes transition metal sources, the compound has the additional advantage of being able to be used as a chalcogen sources when employed as a precursor for manufacturing heterometallic chalcogenide thin films.

In the organometallic compounds represented by Chemical Formula A, which is used in the composition of the present disclosure, the monovalent cations A₁ and A₂ are same or different and preferably may each be independently, P⁺(R₁R₂R₃R₄). The organometallic compounds including P⁺(R₁R₂R₃R₄) are expected to stabilize the layered structure of the metal dichalcogenide thin films by acting as capping agents due to the planar structure of the aryl chains or the chain structure of the alkyl chains in the compound during the thin film manufacturing process.

Furthermore, the central metal (M) used in the organometallic compound represented by Chemical Formula A or B according to the present disclosure may be preferably any one selected from Ni, Co, Fe, Ru, Rh, Pd, Os, Ir, and Pt and more preferably from Ni, Co, Fe, and Pd, with particular preference for Ni when used in an optical sensor.

Moreover, the solution process solution containing the organometallic compound represented by Chemical Formula A or B exhibits good solubility in organic solvents and can form a thin film in the presence of an organic solvent. In this regard, the solution process composition facilitates the formation of a ternary heterometallic chalcogenide thin film in a solution process without additional introduction of a chalcogen component (sulfur or selenium component) because the organometallic compound represented by Chemical Formula A or B bears the chalcogen component therein.

The organic solvent mixed with the organometallic compound is not particularly limited and may preferably include one or more non-polar organic solvents selected from hexane, heptane, octane, nonane, benzene, toluene, xylene, cyclohexane, and cyclooctane, or mixtures thereof. Alternatively, one or more polar organic solvents selected from acetonitrile, dimethyl sulfoxide (DMSO), dimethylformamide, dimethylacetamide, hexamethylphosphoramide, N-methylpyrrolidone, tetrahydrofuran, ethyl acetate, isopropyl alcohol (IPA), and acetone, or mixtures thereof may be used. Preferably, the organometallic compound represented by Chemical Formula A or B includes an ionic part in the form of a salt, allowing the use of polar organic solvents such as acetonitrile, dimethylformamide, dimethyl sulfoxide (DMSO), and isopropyl alcohol (IPA).

Here, the solution process composition of the present disclosure can be prepared by introducing the organometallic compound represented by Chemical Formula A or B into an organic solvent and mixing and stirring same for 5 minutes to 3 days and preferably for 30 minutes to 12 hours.

The solution process composition of the present disclosure may include the organic solvent in an amount of 10 to 99.95 wt %, based on the total weight thereof, preferably in an amount of 50 to 99.9 wt %, more preferably in an amount of 80 to 99.8 wt %, and even more preferably in an amount of 85 to 99.5 wt %, and most preferably in an amount of 92 to 99 wt %.

In addition, the solution process composition of the present disclosure may include the organometallic compound represented by Chemical Formula A or B in an amount of 0.05 to 90 wt %, based on the total weight thereof, preferably in an amount of 0.1 to 50 wt %, more preferably in an amount of 0.2 to 20 wt %, even more preferably in an amount of 0.5 to 15 wt %, still more preferably in an amount of 0.7 to 10 wt %, and most preferably in an amount of 1 to 8 wt %.

Here, if the content of the organometallic compound is too low, the formation rate of the thin film according to the process time is too slow, significantly reducing productivity. If the content of the organometallic compound is too high, the uniformity may be impaired due to the excessive amount of the organometallic compound. Hence, it is desirable to maintain the content within an appropriate range.

The present disclosure provides a method for manufacturing a heterometallic chalcogenide thin film using a solution process composition containing the organometallic compound represented by Chemical Formula A or B, and a thin film obtained by the manufacturing method.

More specifically, the present disclosure provides a method for manufacturing a heterometallic chalcogenide thin film, the method comprising the steps of: (a) coating a substrate with a solution process composition containing the organometallic compound represented by Chemical Formula A or B; and (b) applying heat treatment or external energy to the substrate coated with the solution process composition. This method corresponds to a solution process method in which the organometallic compound (precursor) is dissolved in a solvent, coated on a substrate, and then subjected to heat treatment or energy application to form the thin film.

The substrate used may be any one selected from SiO₂, SiO₂/Si, sapphire, glass, quartz, plastic, and flexible glass (Willow glass). Examples of the plastic substrate include polyethylene terephthalate (PET) and polyimide (PI), but are not limited thereto.

If the organic solvent in the solution process composition is a polar organic solvent, the substrate may be hydrophilically treated before step (a) to enhance the coating film formation of the solution process composition. The hydrophilic treatment of the substrate can preferably be selected from UV light treatment, plasma treatment, piranha treatment, or discharge treatment. The hydrophilic treatment ensures that the solution process composition is evenly dispersed on the substrate surface, improving coating performance.

Methods for coating the solution process composition onto the substrate include spin coating, dip coating, roll coating, screen coating, spray coating, spin casting, flow coating, screen printing, inkjet, or drop casting, with most preference for spin coating in terms of convenience and uniformity. For example, the spin coating method may include: a first coating step at a speed of 300 to 1500 rpm, and a second coating step at a speed of 1000 to 2500 rpm, and preferably a first coating step at a speed of 700 to 900 rpm and a second coating step at a speed of 1500 to 1700 rpm.

Additionally, the manufacturing method according to the present disclosure may further include a pre-heat treatment step to remove residual organic solvent from the substrate after forming the coating film in step (a). This pre-heat treatment step may be a drying step and can be performed at a temperature condition of 50 to 150° C. The heat treatment time is not limited as long as the polar organic solvent can be removed, but may be adjusted within a range of 10 seconds to 10 minutes.

After forming the coating film in step (a) or optionally after the pre-heat treatment step to remove residual organic solvent from the substrate, the heat treatment in step (b) may be carried out at a temperature ranging from 300 to 700° C., preferably from 350 to 600° C., and more preferably from 380 to 500° C. to decompose the cationic components contained in the precursor and the chalcogen elements bonded to heterometals to form a heterometallic chalcogenide material. The heat treatment time for step (b) may range from 10 seconds to 12 hours, preferably from 1 minute to 1 hour. For example, the heat treatment may be performed under an inert gas atmosphere such as argon or nitrogen at a temperature range of 250 to 700° C., preferably 250 to 650° C., and more preferably 300 to 600° C., and may be suitably adjusted or changed depending on the desired composition and properties of the thin film.

For example, the heat treatment process for the thermal decomposition of the solution process composition containing the organometallic compound represented by Chemical Formula A or B may include a pre-heat treatment step for removing the organic solvent at a temperature range of 50 to 120° C. under a pressure of 0.5 torr to 760 torr, preferably 1 torr to 20 torr; and a thermal decomposition step at a temperature range of 300 to 700° C. under a pressure of 0.5 torr to 760 torr, preferably 1 torr to 20 torr.

In each of these heat treatment steps, the heat treatment may be performed under an inert gas atmosphere such as nitrogen or argon, allowing for more stable thermal decomposition.

Furthermore, the present disclosure provides a heterometallic chalcogenide thin film manufactured by the method for manufacturing a heterometallic chalcogenide thin film. Specifically, through the thermal decomposition process according to the present disclosure, a high-quality heterometallic chalcogenide thin film with a uniform surface can be formed. The thin film may be formed as a single-layer or multi-layer structure in a two-dimensional configuration.

Additionally, the present disclosure provides an optical sensor including the heterometallic chalcogenide thin film or an electronic device including the heterometallic chalcogenide thin film.

A better understanding of the present disclosure may be obtained through the following Examples which are set forth to illustrate, but are not to be construed to limit, the present disclosure.

### Precursor Preparation

### Preparation Example 1: Synthesis of (Ph₄P)₂[(MoS₄)Ni(WS₄)]

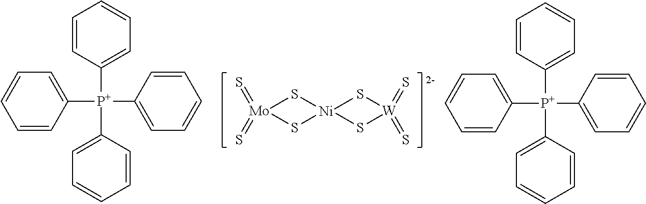

### (Ph₄P)₂[(MoS₄)Ni(WS₄)]

In a 100-ml Schlenk flask, a solution of (NH₄)₂MoS₄ (1 mmol, 0.26 g) in distilled water was stirred at low temperature. To this solution was added a solution of NiCl₂·6H₂O (1.1 mmol, 0.28 g) and Ph₄PCl (2 mmol, 0.65 g) in distilled water, followed by stirring for 5 minutes. Subsequently, a solution of (NH₄)₂WS₄ (1 mmol, 0.35 g) in distilled was added, stirred for 10 minutes, and filtered to obtain the compound as a blackish brown solid. This solid was dried for 18 hours at a reduced pressure and then recrystallized in acetonitrile and diethylether to afford the compound as a reddish brown solid.

EA: Anal. Calcd (Found) for C₄₈H₄₀MoWNiP₂S₈: C, 45.26 (46.15); H, 3.17 (3.21); S, 20.14 (16.59).

EDS (atomic % ratio): Ni 1; Mo 0.93; W 1.12; S 6.42; P 1.98.

### Preparation Example 2: Synthesis of (Ph₄P)₂[(MoS₄)Co(WS₄)]

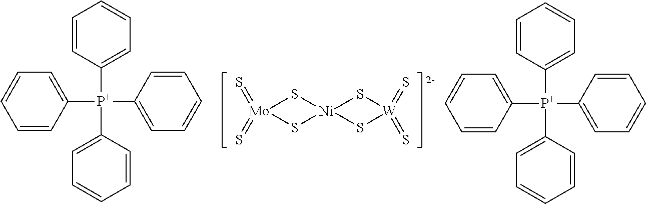

### (Ph₄P)₂[(MoS₄)Co(WS₄)]

In a 100-ml Schlenk flask, a solution of (NH₄)₂MoS₄ (1 mmol, 0.26 g) in distilled water was stirred at low temperature. To this solution was added a solution of COCl₂·6H₂O (1 mmol, 0.24 g) and Ph₄PCl (2 mmol, 0.65 g) in distilled water, followed by stirring for 5 minutes. Subsequently, a solution of (NH₄)₂WS₄ (1 mmol, 0.35 g) in distilled water was added, stirred for 10 minutes, and filtered to obtain the compound as a dark green solid. This solid was dried for 18 hours at a reduced pressure and recrystallized in DMF and diethylether to afford the compound as a reddish brown solid.

EA: Anal. Calcd (Found) for C₄₈H₄₀MoWCoP₂S₈: C, 45.25 (45.0); H, 3.16 (3.02); S, 20.13 (13.82).

EDS (atomic % ratio): Co 1; Mo 0.93; W 0.98; S 7.03; P 2.05.

### Preparation Example 3: Synthesis of (Ph₄P)₂[(MoS₄)Fe(WS₄)]

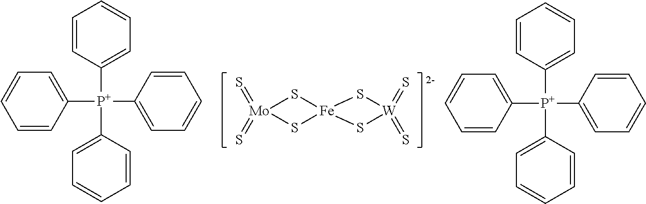

### (Ph₄P)₂[(MoS₄)Fe(WS₄)]

In a 100-ml Schlenk flask, a solution of (NH₄)₂MoS₄ (1 mmol, 0.26 g) in distilled water was stirred at low temperature. To this solution was added a solution of FeCl₂·4H₂O (1 mmol, 0.198 g) and Ph₄PCl (2 mmol, 0.65 g) in distilled water, followed by stirring for 5 minutes. Subsequently, a solution of (NH₄)₂WS₄ (1 mmol, 0.35 g) in distilled water was added, stirred for 10 minutes, and filtered to obtain the compound as a solid. This solid was dried for 18 hours at a reduced pressure and then recrystallized in DMF and diethylether to afford the compound as a solid.

### Preparation Example 4: Synthesis of

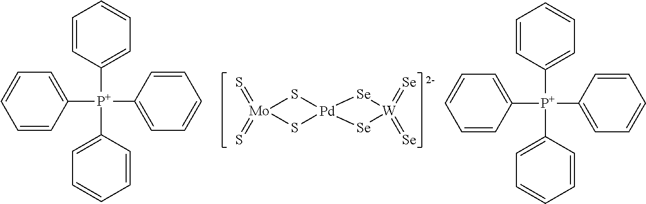

### (Ph₄P)₂[(MoS₄)Pd(WSe₄)]

In a 50-ml Schlenk flask, a solution of (Ph₄P)₂WSe₄ (0.1 mmol, 0.09 g) in DMF was stirred at low temperature. To this solution was added a solution of PdCl₂(CNC₆H₅) (0.1 mmol, 0.038 g) and Et₄NCl (0.2 mmol, 0.033 g) in DMF, followed by stirring for 5 minutes. Subsequently, a solution of (Ph₄P)₂MOS₄ (1 mmol, 0.35 g) in DMF was added, stirred for 18 hours, and filtered before being added dropwise to diethyl ether. After 18 hours at 0° C., a dark reddish solid was precipitated. Filtration and washing with methanol afforded the compound as a reddish solid.

EA: Anal. Calcd (Found) for C48H₄₀MoP₂PdS₄Se₄W: C, 17.62 (16.65); H, 3.70 (3.73); S, 11.76 (13.19); N, 2.57 (3.43)

EDS (atomic % ratio): Pd 1; Mo 0.87; W 1.1; S 4.03; Se 4.87; P 1.82.

### Preparation Example 5: Synthesis of (Et₄N)₂[(MoS₄)Pd(WSe₄)]

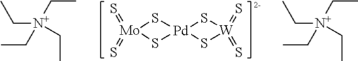

### (Et₄N)₂[(MOS₄)Pd(WSe₄)]

In a 50-ml Schlenk flask, a solution of (NH₄)₂MOS₄ (0.5 mmol, 0.13 g) in DMF was stirred at low temperature. To this solution was added a solution of PdCl₂(CNC₆H₅) (0.5 mmol, 0.19 g) in DMF, followed by stirring for 5 minutes. Subsequently, a solution of (Et₄N)₂WSe₄ (0.5 mmol, 0.478 g) in DMF was added, stirred for 18 hours, and filtered before being added dropwise to diethyl ether. After 18 hours at 0° C., a dark reddish solid was precipitated. Filtration and washing with methanol afforded the compound as a reddish solid.

EA: Anal. Calcd (Found) for C₄₈H₄₀MOWCOP₂S₈: C, 45.25 (45.0); H, 3.16 (3.02); S, 20.13 (13.82).

EDS (atomic % ratio): Co 1; Mo 0.93; W 0.98; S 7.03; P 2.05.

### Preparation Example 6: Synthesis of (imidazolinium)₂[(MOS₄)Pd(WSe₄)]

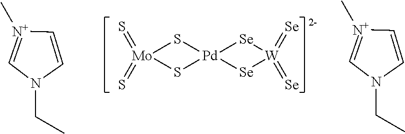

### (imidazolinium)₂[(MOS₄)Pd(WSe₄)]

In a 50-ml Schlenk flask, a solution of (NH₄)₂MoS₄ (0.2 mmol, 0.056 g) in DMF was stirred at low temperature. To this solution was added a solution of PdCl₂(CNC₆H₅)₂ (0.2 mmol, 0.077 g) in DMF, followed by stirring for 10 minutes. Subsequently, a solution of (imidazolinium)₂WSe₄ (0.2 mmol, 1.44 g) in DMF was added, stirred for 18 hours, and filtered. Recrystallization in diethylether afforded the compound as a blackish solid.

EA: Anal. Calcd (Found) for C₁₂H₂₂MON₄PdS₄Se₄W: C, 13.69 (13.66); H, 2.11 (2.13); S, 12.18 (13.09); N, 5.32 (5.18).

EDS (atomic % ratio): Pd 1; Mo 0.74; W 1.55; S 3.48; Se 4.95.

### Preparation Example 7: Synthesis of (Ph₄P)₂[(MoS₄)Pd(WS₄)]

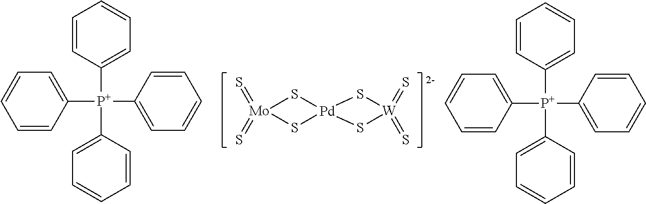

### (Ph₄P)₂[(MoS₄)Pd(WS₄)]

In a 100-ml Schlenk flask, a solution of (NH₄)₂MoS₄ (1 mmol, 0.26 g) in DMF was stirred at low temperature. To this solution was added a solution of PdCl₂(CNC₆H₅)₂ (1 mmol, 0.24 g) and Ph₄PCl (2 mmol, 0.65 g) in DMF, followed by stirring for 10 minutes. Subsequently, a solution of (NH₄)₂WS₄ (1 mmol, 0.35 g) in DMF was added, stirred for 18 hours, and filtered. Recrystallization in diethylether afforded the compound as a green solid.

EA: Anal. Calcd (Found) for C₄₈H₄₀MoWPdP₂S₈: C, 43.63 (43.46); H, 3.05 (3.25); S, 19.41 (18.28).

### Preparation Example 8: Synthesis of (Ph₄P)₂[Ni(MoS₄)₂]

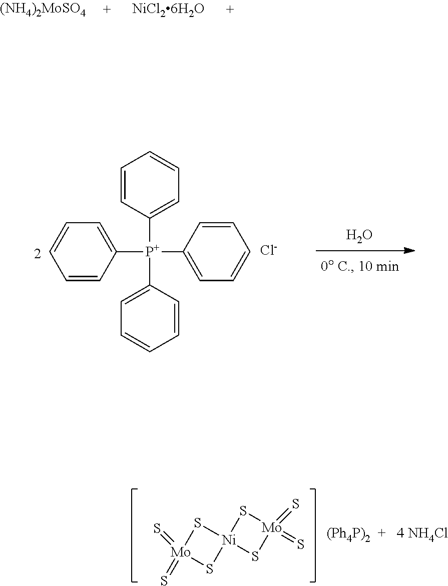

In a 100-ml Schlenk flask, a solution of (NH₄)₂MoS₄ (2 mmol, 0.52 g) in distilled water was stirred at 0° C. To this solution was added a solution of NiCl₂·6H₂O (1.1 mmol, 0.28 g) and Ph₄PCl (2 mmol, 0.65 g) in distilled water, followed by stirring for 10 minutes and filtration to obtain the compound as a blackish brown solid. This solid was dried for 18 hours at a reduced pressure and recrystallized in nitromethane and diethylether to afford the compound as a reddish brown solid.

(yield 64%)

EA: Anal. Calcd (Found) for C₄₈H₄₀MoWNiP₂S₈: C, 45.26 (46.15); H, 3.17 (3.21); S, 20.14 (16.59).

EDS (Atomic % ratio): Ni 1.00; Mo 0.93; W 1.12; S 6.42; P 1.98

### Example 1: Crystal Structure Analysis of Compounds

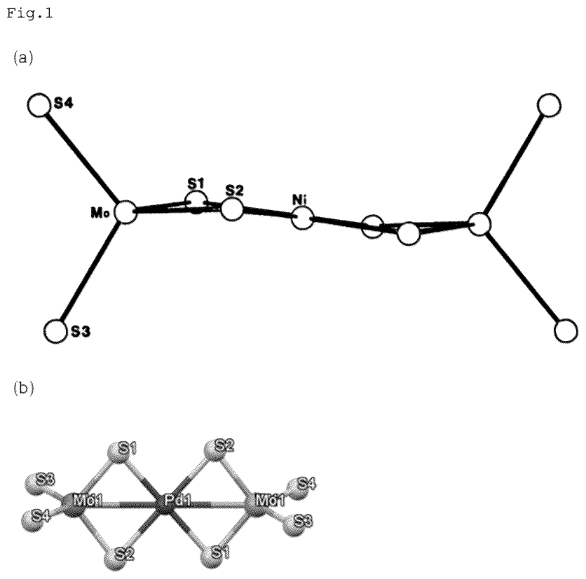

Examination was made of the crystal structures of the organometallic compounds ((Ph₄P)₂[Ni(MoS₄)₂] synthesized in Preparation Example 8 and (Ph₄P)₂[(MoS₄)Pd(WS₄)] synthesized in Preparation Example 7). In this regard, X-ray structures were confirmed using a SMART APEX II X-ray Diffractometer. The crystal structures of the compounds are depicted in FIGS. 1(a) and 1(b), respectively.

### Example 2: Thermal Properties Analysis of Compounds

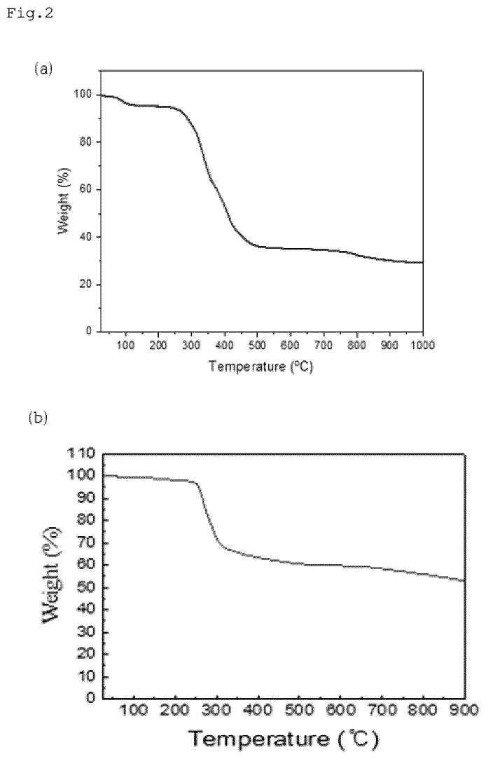

To measure the thermal stability, volatility, and decomposition temperature of the organometallic compounds ((Ph₄P)₂[Ni (MoS₄)₂] synthesized in Preparation Example 8 and (Ph₄P)₂[(MoS₄)Pd(WS₄)] synthesized in Preparation Example 7), thermogravimetric analysis (TGA) was performed. In the TGA method, the products were heated up to 900° C. at a rate of 10° C./min while argon gas was injected at a pressure of 1.5 bar/min. The results of the thermal decomposition experiments for the compound from Preparation Example 8 are depicted in FIG. 2(a), and the results for the compound from Preparation Example 7 are shown in FIG. 2(b).

According to the thermal properties analysis results shown in FIG. 2(a), it was observed that the precursor compound from Preparation Example 8 had a final residue of 30.3%, and the organometallic compound synthesized in Preparation Example 7 had a final residue of 52.96%.

The TGA analysis results indicate that the organometallic compounds according to the present disclosure possess favorable properties for forming metal thin films, metal oxide thin films, or metal chalcogenide thin films.

### Example 3: Manufacturing of Thin Films by Spin Coating

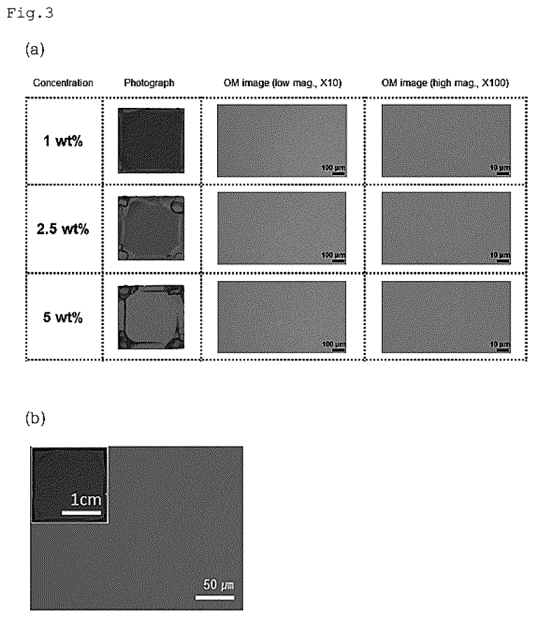

A 5 wt % solution of the organometallic compound obtained in Preparation Example 8 in dimethylformamide was spin-coated onto SiO₂ (300 nm)/Si(001) substrate previously treated for 60 seconds with UV. The spin coating was carried out at 0 rpm for 30 seconds and at 1000 rpm/2000 rpm for 20 seconds. Subsequently, dimethylformamide was evaporated at 100° C. to form a thin film derived from (Ph₄P)₂[Ni(MoS₄)₂]. The formed thin film was measured for uniformity under an optical microscope and the results are depicted in FIG. 3(a), indicating that the thin film was well-formed.

Similarly, a 5 wt % solution of the organometallic compound obtained in Preparation Example 7 in dimethylformamide was spin-coated onto a SiO₂ (300 nm)/Si(001) substrate previously treated for 60 seconds with UV. The spin coating was performed at 0 rpm for 30 seconds and at 1000 rpm/2000 rpm for 20 seconds. Subsequently, dimethylformamide was evaporated at 100° C. to form a thin film derived from (Ph₄P)₂[(MoS₄)Pd(WS₄)]. The formed thin film was measured for uniformity under an optical microscope and the results are depicted in FIG. 3(b), indicating that the thin film was well-formed.

### Example 4: Synthesis of NiₓMo_{y}S_{z} Ternary Layered Material (Synthesis of 2D Material by Thermal Decomposition of Organometallic Compound Obtained in Preparation Example 8)

A 5 wt % solution of the organometallic compound (Ph₄P)₂Ni(MoS₄)₂ obtained from Preparation Example 8 in dimethylformamide (DMF) was stirred at room temperature for 180 minutes to prepare a precursor solution. Afterward, substrate coatability was enhanced. In this regard, the SiO₂ (300 nm)/Si(001) substrate was treated with UV for 60 seconds to render the surface hydrophilic. The precursor solution was then spin-coated onto the hydrophilic-treated substrate. The spin coating was performed at a speed of 1000 rpm for 20 seconds. Subsequently, the coated substrate was placed on a hot plate and pre-heated at 100° C. for 2 minutes to dry and remove the solvent. The dried precursor thin film-coated substrate was then placed inside a furnace and heated at 400° C., 500° C., and 600° C. under a pressure of 1.5 Torr while argon gas (Ar) was supplied at a flow rate of 1000 sccm for 30 minutes to synthesize NiMoS₂ heterometallic chalcogenide material on the SiO₂/Si substrate.

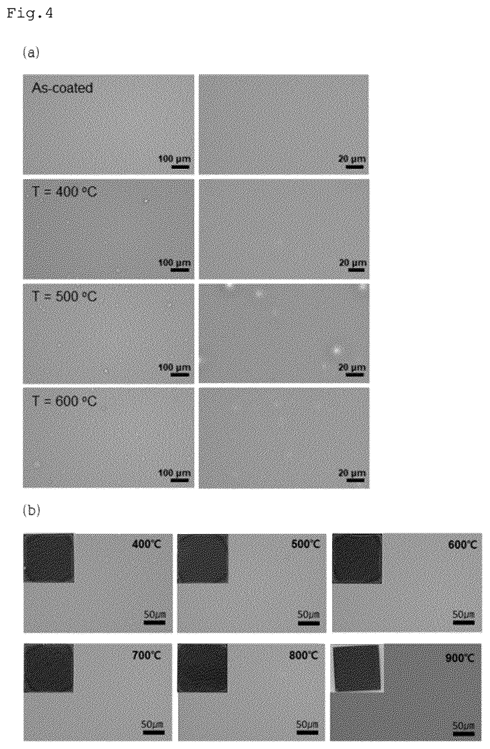

FIG. 4(a) shows optical microscope images of the thin film (As coated) immediately after spin coating and the heterometallic chalcogenide (NiₓMo_{y}S_{z}) thin films synthesized at 400° C., 500° C., and 600° C. according to the thermal decomposition conditions in Example 4.

### Example 5: Synthesis of PdₓMo_{y}W_{y}S_{z} Quaternary Layered Material (Synthesis of 2D Material by Thermal Decomposition of Organometallic Compound Obtained in Preparation Example 7)

A 5 wt % solution of the organometallic compound obtained in Preparation Example 7 in dimethylformamide was spin-coated onto a SiO₂ (300 nm)/Si(001) substrate previously treated with UV for 600 seconds. The spin coating was performed at 0 rpm for 30 seconds and at 1000 rpm/2000 rpm for 20 seconds. Afterward, the coated substrate was pre-heated at 100° C. for 2 minutes to evaporate the dimethylformamide and synthesize the PdₓMo_{y}W_{y}S_{z} thin film. The dried precursor thin film-coated substrate was then placed inside a furnace and heated at 400° C., 500° C., 600° C., 700° C., 800° C., and 900° C. under a pressure of 1.5 Torr while argon gas (Ar) was supplied at a flow rate of 1000 sccm for 30 minutes to synthesize the PdMoWS₂ heterometallic chalcogenide material on the SiO₂/Si substrate.

FIG. 4(b) shows optical microscope images of the WMoPd_{0.5}S_{1.8} heterometallic chalcogenide thin films synthesized at 400° C., 500° C., 600° C., 700° C., 800° C., and 900° C. according to the thermal decomposition conditions in Example 5, respectively.

### Example 6: X-Ray Photoelectron Spectroscopy

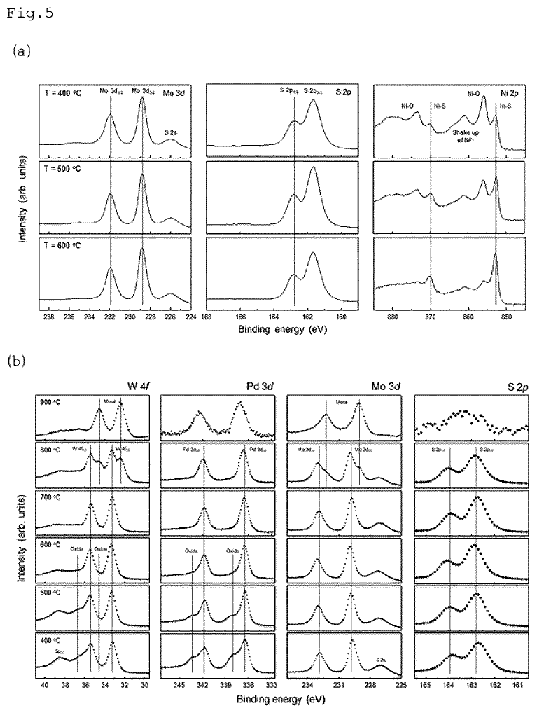

X-ray photoelectron spectroscopy (XPS, 3×6 mm²) spectra for the two-dimensional heterometallic chalcogenide NiₓMo_{y}S_{z} thin film manufactured in Example 4 are given in FIG. 5(a). As shown in FIG. 5(a), the Mo 3d, S 2p, and Ni 2p core level spectra of the two-dimensional heterometallic chalcogenide (NiₓMo_{y}S_{z}) thin film synthesized according to the present disclosure confirmed the presence of Mo, S, and Ni elements in the sample. The Ni 2p spectrum indicated a decrease in Ni—O bond-related peaks and an increase in Ni—S bond-related peaks as the temperature increased from 400° C. to 600° C. This confirmed that the optimal synthesis temperature was 600° C. At 600° C., the ratio of Ni, Mo, and S was determined to be Ni_{0.08}Mo_{0.35}S_{0.57}.

Additionally, X-ray photoelectron spectroscopy (XPS, 3×6 mm²) spectra for the two-dimensional heterometallic chalcogenide PdₓMoW_{y}S_{z} thin film manufactured in Example 5 are depicted in FIG. 5(b). The W 4 f, Pd 3 d, Mo 3 d, S 2 p core level spectra of the two-dimensional heterometallic chalcogenide (PdₓMo_{y}W_{y}S_{z}) thin film synthesized according to the present disclosure confirmed the presence of W, Mo, S, and Ni elements in the sample.

The W4 f core level spectrum results showed that bonding states related to W oxide were observed in the high binding energy region for samples formed in the 400-600° C. temperature range. At higher temperatures of 800° C. and 900° C., metallic W-related bonding states attributed to desulfurization were observed in the low binding energy region.

The Pd 3d core level spectrum analysis indicated oxide-related bonding states in the 400-600° C. temperature range, like the chemical state change of W, and a decrease in peak intensity at 900° C. due to evaporation.

The Mo 3d core level spectrum showed metallic Mo due to desulfurization at temperatures above 800° C., with the desulfurization effect being more pronounced at 900° C. in the S 2p core level spectrum.

### Example 7: Raman Spectroscopy

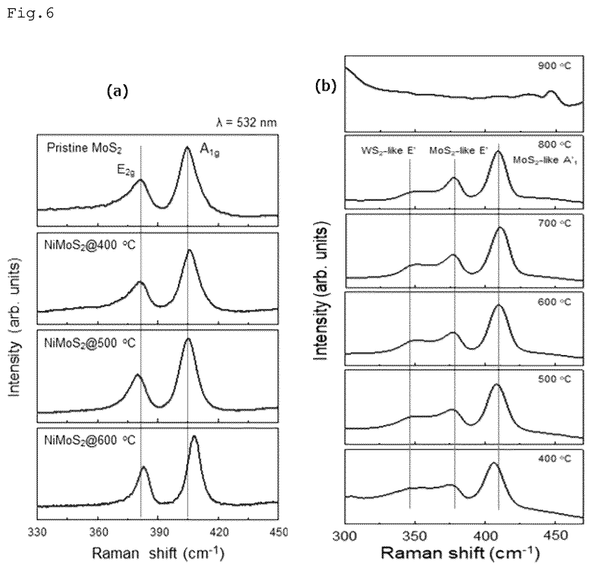

The Raman spectra of the two-dimensional heterometallic chalcogenide (NiₓMo_{y}S_{z}) thin film manufactured in Example 4 are given in FIG. 6(a). As shown in FIG. 6(a), the Raman spectroscopy results indicated a blueshift in the E_{2g} and A_{1g} phonon modes as the heat treatment temperature increased. This effect is attributed to tensile strain due to the substitution of Ni in the MoS₂ crystal. The decrease in the FWHM of each peak at the optimal synthesis temperature of 600° C. confirmed the synthesis of highly crystalline Ni_{0.08}Mo_{0.35}S_{0.57} with a low density of intrinsic vacancies.

The Raman spectra of the two-dimensional heterometallic chalcogenide (PdₓMo_{y}W_{y}S_{z}) thin film manufactured in Example 5 are given in FIG. 6(b). As shown in FIG. 6(b), MoS₂-like A′₁ and E′ modes that were observed at wavenumbers similar to the phonon modes typically observed in MoS₂ were observed to coexist with WS₂-like E′ phonon modes that were observed in the regions similar to the phonon mode typically observed for WS₂. The absence of Pd—S bond-related phonon modes is presumed to be due to the relatively low concentration of Pd in the crystal. Except for the 900° C. condition, an increase in the decomposition temperature resulted in a decrease in the FWHM of each peak, indicating improved crystallinity.

### Example 8: Transmission Electron Microscopy/Energy Dispersive X-ray Spectroscopy (EDS) Mapping

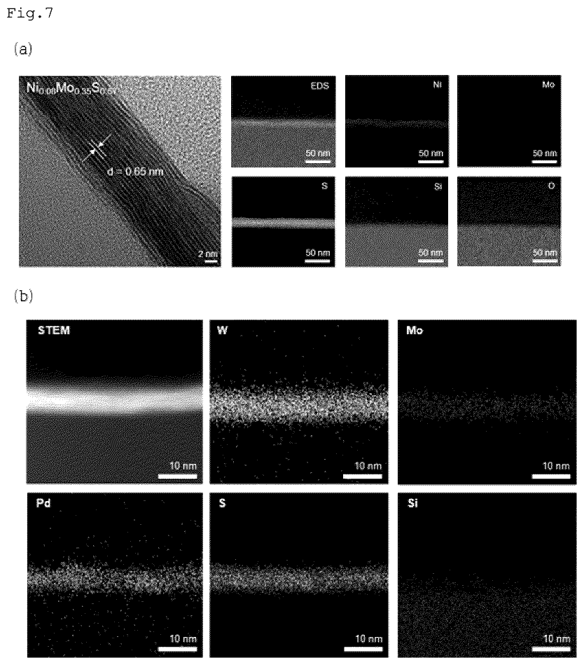

Transmission electron microscopy images and energy dispersive X-ray spectroscopy elemental mapping results for the heterometallic chalcogenide (Ni_{0.08}Mo_{0.35}S_{0.57}) thin film synthesized at 600° C. in Example 4 are shown in FIG. 7(a). As shown FIG. 7(a) (left panel), the transmission electron microscopy image of the heterometallic chalcogenide (Ni_{0.08}Mo_{0.35}S_{0.57}) thin film synthesized at 600° C. according to the present disclosure reveals a multilayer structure with 20 layers, a thickness of 12.4 nm, and an interlayer spacing of 0.65 nm, which is similar to the reported interlayer spacing of Ni-doped MoS₂ crystals (0.64 nm) [Nano Research, 9, 2284 (2016)]. Additionally, the EDS elemental mapping results on the right panels of FIG. 7(a) show that Ni, Mo, and S are very uniformly distributed within the two-dimensional layered material.

Scanning transmission electron microscopy images and energy dispersive X-ray spectroscopy elemental mapping results for the two-dimensional heterometallic chalcogenide (WMoPd_{0.5}S_{0.8}) thin film synthesized in Example 5 are given in FIG. 7(b). As shown in FIG. 7(b) (upper left panel), the scanning transmission electron microscopy image of the heterometallic chalcogenide (WMoPd_{0.5}S_{0.8}) thin film synthesized according to the present disclosure indicates a multilayer structure with a thickness of 7 nm and an interlayer spacing of 0.71 nm. Additionally, the EDS elemental mapping results in the upper center, upper right, and lower panels of FIG. 7(b) show that W, Mo, Pd, and S are very uniformly distributed within the two-dimensional layered material.

### Example 9: Atomic Force Microscopy (AFM)

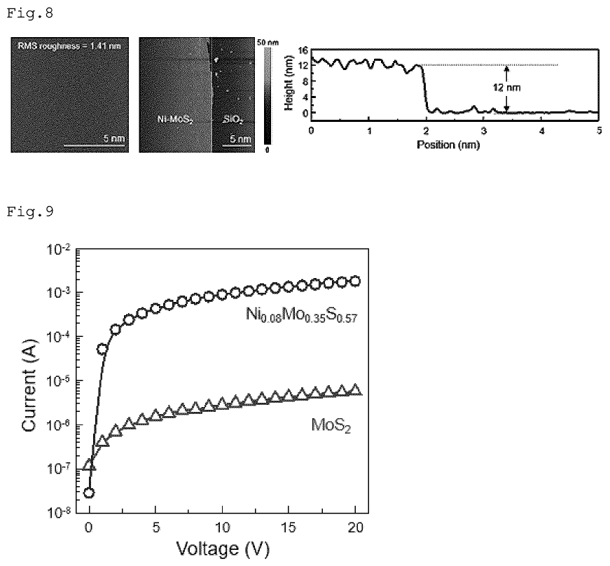

The atomic force microscopy (AFM) images of the heterometallic chalcogenide (Ni_{0.08}Mo_{0.35}S_{0.57}) thin film synthesized at 600° C. in Example 4 are given in FIG. 8. As shown in FIG. 8, the surface roughness (RMS roughness) was found to be 1.41 nm, indicating a very flat surface. Consistent with the TEM observation results, the film thickness was confirmed to be approximately 12 nm.

### <Fabrication and Characterization of Photodetectors>

### Example 10: Fabrication of Two-Terminal Photodetector with WMoPd_{0.5}S_{1.8} Quaternary Layered Material

To evaluate the applicability of the thin films obtained from the composition of the present disclosure as photodetectors, a photodetector was fabricated on a SiO₂ (300 nm)/Si(001) substrate. Using the previously synthesized 2D WMoPd_{0.5}S_{1.8} quaternary semiconductor material, Cr and Au were patterned to thicknesses of 3 nm and 70 nm, respectively, using thermal evaporation to create the photodetector.

### Example 11: Fabrication of Two-Terminal Photodetector with NiMoS₂ Ternary Layered Material

Onto selective regions of the Ni_{0.08}Mo_{0.35}S_{0.57} thin film formed on a SiO₂/Si substrate through the heat treatment process at 600° C. in Example 4, Cr (3 nm) and Au (70 nm) were sequentially deposited using thermal evaporation and a shadow mask to fabricate a two-terminal photodetector.

### Example 12: Analysis for Optical Properties of Photodetector

The optical properties of the photodetector fabricated in Example 11 were measured and compared with those of a conventional MoS₂ photodetector, as shown in FIG. 9.

As indicated in FIG. 9, the current-voltage characteristics of the Ni_{0.08}Mo_{0.35}S_{0.57} thin film photodetector fabricated in Example 11 show that the current generated at the same voltage is more than 300 times higher than that of the MoS₂-based photodetector.

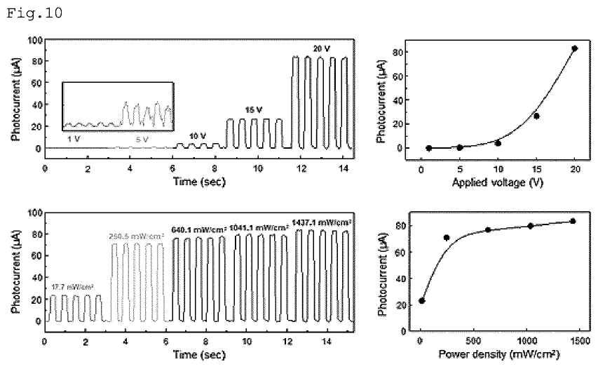

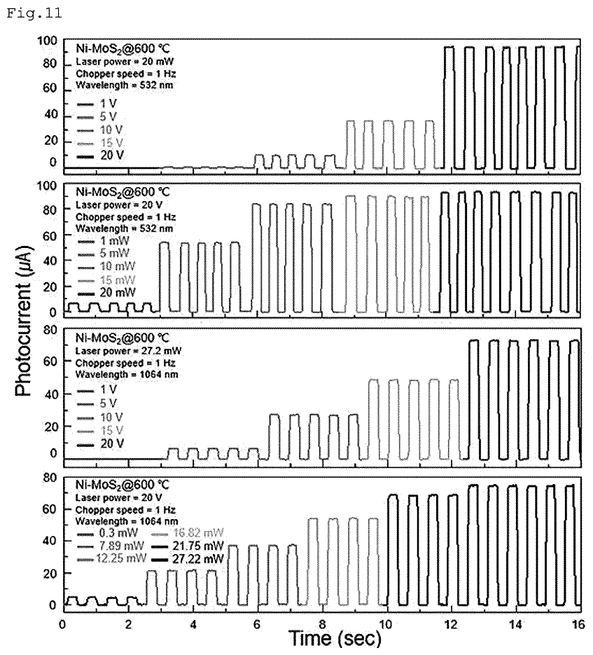

FIG. 10 shows the photoelectric characteristics of the sensor fabricated in Example 10 under different applied voltages and light intensities (532 nm visible light). FIG. 11 presents the photoelectric characteristics of the sensor fabricated in Example 11 under different applied voltages and light intensities for both visible light (532 nm) and near-infrared light (1064 nm).

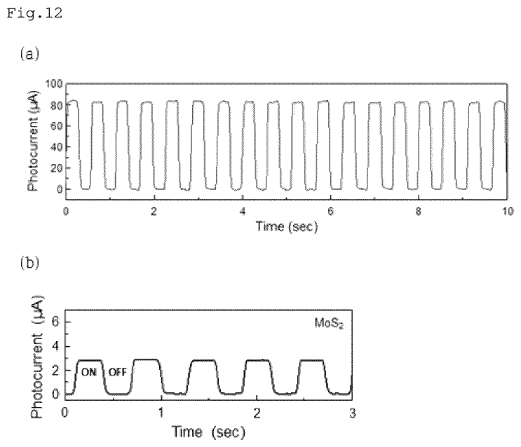

FIG. 12(a) shows the photoelectric characteristics of the WMoPd_{0.5}S_{1.8} layered material under visible light (532 nm), and FIG. 12(b) presents the photoelectric characteristics of the MoS₂ semiconductor layered material under the same conditions.

As shown in FIGS. 10 and 11, the sensors fabricated according to the present disclosure exhibit excellent response characteristics to the ON/OFF state of each light source, regardless of the wavelength (visible or near-infrared). The photo-current increases with higher applied voltages and light intensities.

Additionally, as indicated in FIG. 11, the photo-currents measured under visible light (532 nm, 20 mW, 20 V) and near-infrared light (1064 nm, 27.22 mW, 20 V) were 93.7 μA and 72.5 μA, respectively. These values are significantly higher at the same voltage than the photo-current (3 μA) of MoS₂ synthesized via coating/thermal decomposition of a single precursor solution, as reported in FIG. 12(b).

While the present disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. An organometallic compound represented by the following Chemical Formula A or B: 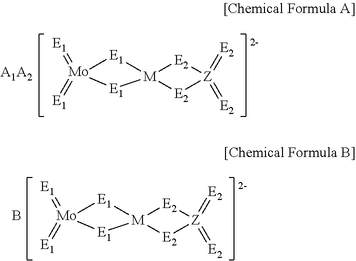
wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄+, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20,
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

2. The organometallic compound of claim 1, wherein A₁ and A₂, which are same or different, are each independently P⁺(R₁R₂R₃R₄).

3. The organometallic compound of claim 2, wherein R₁ to R₄, which are same or different, are each independently any one selected from a substituted or unsubstituted aryl of C6-C20 and a substituted or unsubstituted heteroaryl of C2-C20.

4. The organometallic compound of claim 3, wherein R₁ to R₄ are all same.

5. A method for manufacturing a metal chalcogenide thin film, using the organometallic compound of any one of claims 1 to 4 as a metal precursor.

6. The method of claim 5, wherein the manufacturing of the metal chalcogenide thin film is carried out by a solution process.

7. A method for manufacturing an organometallic compound represented by Chemical Formula A or B of claim 1, using a metal halide compound represented by the following Compound M, a molybdenum chalcogenide represented by the following Compound C1, and a transition metal chalcogenide represented by the following Compound C2 as respective reactants: 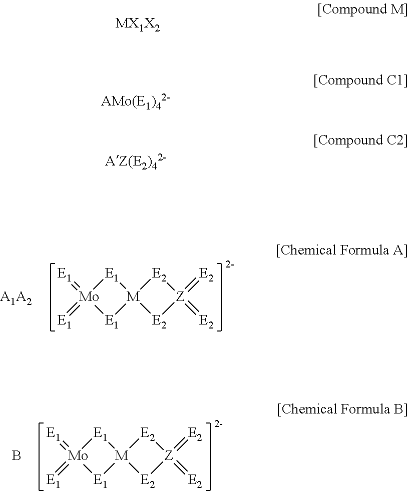
in Compound M,
X₁ and X₂, which are same or different, are each independently a halogen atom selected from F, Cl, Br, and I,
in Chemical Formulas C1 and C2,
A means a divalent cation or two identical or different monovalent cations corresponding to Mo(E₁)₄²⁻,
A′ means a divalent cation or two identical or different monovalent cations corresponding to Z(E₂)₄²⁻,
in Chemical Formula C2,
Z is Mo or W,
in Chemical Formulas A and B and Compounds C1 and C2,
E₁ and E₂, which are same or different, are each independently sulfur (S) or selenium (Se), and
M, Z, A₁, A₂, and B in Compound M and Chemical Formulas A and B are each as defined in claim 1.

8. The method of claim 7, wherein a complex obtained after the reaction of the metal halide compound represented by Compound M, the molybdenum chalcogenide represented by Compound C1, and the transition metal chalcogenide represented by Compound C2 is reacted with a salt containing A₁ and A₂ or a salt containing B through cation exchange to afford the organometallic compound represented by Chemical Formula A or B of claim 1.

9. A solution process composition for forming heterometallic chalcogenide thin film, the composition comprising an organometallic compound represented by the following Chemical Formula A or B: 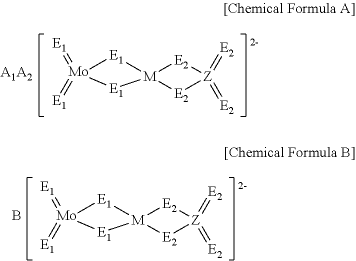
wherein,
Z is Mo or W,
M is a metal element selected from Ni, Co, Fe, Ru, Rh, Pd, Os, Ir, Pt, Ti, Al, Cu, Mg, V, B, Cr, Zr, and Zn,
E₁ and E₂, which are same or different, are each independently sulfur (S) or selenium (Se),
A₁ and A₂, which are same or different, are each independently a monovalent cation selected from H⁺, Li⁺, Na⁺, K⁺, Rb⁺, Cs⁺, NH₄+, N⁺(R₁R₂R₃R₄), a monovalent imidazole cation of 1 to 10 carbon atoms, a monovalent pyridine cation of 1 to 10 carbon atoms, and P⁺(R₁R₂R₃R₄),
B is a divalent cation selected from Ca²⁺, Mg²⁺, (R₁R₂R₃)N⁺—R—N⁺(R₄R₅R₆), (R₁R₂R₃)P⁺—R—P⁺(R₄R₅R₆), Mg²⁺(NR₁R₂R₃)₆, Ni²⁺(NR₁R₂R₃)₆, and Co²⁺(NR₁R₂R₃)₆ wherein the R₁ to R₃-containing amine radicals coordinated respectively to Mg, Ni, and Co are same or different,
R₁ to R₆, which are same or different, are each independently any one selected from a hydrogen atom, a deuterium atom, a substituted or unsubstituted linear, branched, or cyclic alkyl of C1-C20, a substituted or unsubstituted aryl of C6-C20, a substituted or unsubstituted arylalkyl of C7-C20, an alkylaryl of C7-C20, and a substituted or unsubstituted heteroaryl of C2-C20,
R is any one selected from a substituted or unsubstituted linear, branched, or cyclic alkylene of C1-C20, a substituted or unsubstituted cycloalkylene of C1-C2, a substituted or unsubstituted arylene of C6-C20, and a substituted or unsubstituted heteroarylene of C2-C20,
wherein the term “substituted” in the expression “substituted or unsubstituted” used for the compounds of Chemical Formulas A and B means having at least one substituent selected from the group consisting of a deuterium atom, a cyano, a halogen, a nitro, a linear, branched, or cyclic alkyl of C1-C10, and an aryl of C6-C12.

10. The solution process composition of claim 9, wherein A₁ and A₂, which are same or different, are each independently P⁺(R₁R₂R₃R₄).

11. The solution process composition of claim 9, comprising the organometallic compound represented by the following Chemical Formula A or B in an amount of 0.05 to 90 wt %, based on the total weight thereof.

12. A method for manufacturing a heterometallic chalcogenide thin film, the method comprising the steps of:
(a) coating a substrate with a solution process composition of any one of claims 9 to 11; and
(b) applying heat treatment or external energy to the substrate coated with the solution process composition.

13. The method of claim 12, wherein the heat treatment in step (b) is carried out in a temperature range of 300 to 700° C.

14. The method of claim 12, wherein the substrate is subjected to hydrophilic treatment on the surface thereof before step (a).

15. A heterometallic chalcogenide thin film, manufactured by the manufacturing method of claim 12.

16. A photosensor comprising the heterometallic chalcogenide thin film of claim 15.

17. An electronic device comprising the heterometallic chalcogenide thin film of claim 15.
